(19) United States
(12) Patent Application Publication
(10) Pub. No.: US 2001/0053068 A1
(43) Pub. Date: Dec. 20, 2001

(54) Electronic circuit device

(76) Inventors: Toshihiro Murayama, Kanagawa (JP); Yasufumi Tatsuno, Tokyo (JP); Yoshihiko Imai, Aichi (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/809,772

(22) Filed: Mar. 16, 2001

(30) Foreign Application Priority Data
Mar. 16, 2000 (JP) P2000-074119

(51) Int. Cl. H05K 1/14; H05K 1/11

(52) U.S. Cl. 361/760; 361/804; 361/803; 361/784

(57) ABSTRACT

In an electronic circuit device having such a structure that a plurality of circuit boards are stacked, when the circuit boards are stacked, one ends of metal pieces serving as spacers are joined to one circuit board by solder while the other ends of the metal pieces are joined to the other circuit by conductive adhesive agent, whereby the circuit boards can be easily separated from each other at the connection portion and a rework of the parts sandwiched between the circuit boards can be easily performed.

### RELATED APPLICATION DATA

The present application claims priority to Japanese Application No. P2000-074119 filed Mar. 16, 2000, which application is incorporated herein by reference to the extent permitted by law.

### BACKGROUND OF THE INVENTION

The present invention relates to an electronic circuit device, and particularly to an electronic circuit device formed by three-dimensionally fabricating a plurality of circuit boards on which electronic parts are mounted.

An electronic circuit device is formed by etching copper foil joined on a circuit board formed of insulating material to form a wiring pattern, mounting electronic parts on the circuit board and then connecting the electronic parts to the wiring pattern. In order to miniaturize such an electronic circuit, the electronic parts are further reduced in size and the high-density mounting of the electronic parts is carried out. Particularly in connection with the miniaturization of electronic equipment containing an electronic circuit, the high-density mounting of electronic parts is being required more and more. From the viewpoint of the limitation of the two-dimensional high-density mounting as described above, there have been various technical proposals in which electronic parts are three-dimensionally mounted (packaged) to fabricate an electronic circuit.

For example, Japanese Patent Laid-open No. 275838/1993 proposes such a structure that surface mounting parts such as chips, resistors and capacitors are sealingly contained in the inner space between plural circuit boards.

In this structure, a semiconductor device 3 and other electronic parts are mounted on at least one of the surfaces of upper and lower circuit boards 1, 2 which are confronted to each other as shown in FIG. 9. Further, other surface mounting parts 4, a semiconductor device, etc. are mounted on the outer surfaces of the circuit boards 1, 2. The inner space formed by the circuit boards 1, 2 is sealed by sealing resin 5. The electrical connection (conduction) between the upper and lower circuit boards 1, 2 is performed through a through hole 6.

Japanese Patent Laid-open No. 156395/1988 discloses another structure for connecting plural circuit boards. According to this publication, plural circuit boards are stacked through respective spacer boards, and the upper and lower boards are joined to each other by soldering material or the like.

FIG. 10 shows an example of this structure.

In this case, surface mounting parts 4 and a semiconductor device are mounted on each of the outer surfaces of the upper and lower circuit boards 1, 2, and a semiconductor device 3 and surface mounting parts are further mounted on at least one of the confronting surfaces of the upper and lower circuit boards 1, 2 (e.g., the surface of the circuit board 2). A pair of circuit boards 1, 2 are mutually assembled through a spacer board 7. The land of the spacer board 7 and the land of each of the upper and lower circuit boards 1, 2 are joined to each other by solder 8, whereby the conduction between the upper and lower circuit boards 1, 2 is achieved.

In the conventional structure shown in FIG. 9, the parts 3 contained between the upper and lower circuit boards 1, 2 are covered by sealing resin 5 such as epoxy resin and the upper and lower circuit boards 1, 2 are laminated. Therefore, when a circuit board device thus formed is examined and a faulty component is found through the examination at the stage that the circuit device is completed, for example the semiconductor device 3 or the other surface mounting parts which are sealed by the sealing resin 5 cannot be exchanged by another one.

In the structure shown in FIG. 10, when the circuit boards 1, 2 laminated by the soldering joint are detached from each other, it is required to melt the solder 8 through which the spacer board 7 is joined to the upper and lower circuit boards 1, 2. Accordingly, it is required to heat the joint portion to the melting point of the solder or more. At this time, not only the joint portion of the board 7 serving as the spacer, but also peripheral parts are heated. These parts may be deteriorated by heat. Further, a worker must carry out the detaching work while taking care not to touch parts which are easily moved due to melting of solder, so that the workability is low and the disassembly working is hard.

### SUMMARY OF THE INVENTION

The present invention has been implemented in view of the foregoing problems, and has an object to provide an electronic circuit device in which a plurality of assembled circuit boards can be easily separated from one another and a disassembling work can be easily performed when faulty components are found through an examination after fabrication.

In order to attain the above object, according to a first aspect of the present invention, there is provided an electronic circuit device including a plurality of circuit boards which have electronic parts mounted thereon and are three-dimensionally assembled, wherein the plural circuit boards are stacked in the thickness direction through metal pieces at least one ends of which are fixed to the circuit boards. Here, both ends of each metal piece are fixed to the circuit boards at both the sides thereof by materials which are different in melting point (temperature).

According to another aspect of the present invention, there is provided an electronic circuit device including a plurality of circuit boards which have electronic parts mounted thereon and are three-dimensionally assembled, wherein the plural circuit boards are assembled in the thickness direction through spacers each of which comprises a metal piece, and one end of each metal piece is fixed to one circuit board by solder while the other end of the metal piece is fixed to another circuit board by adhesive agent having a melting point (temperature) lower than the solder. Here, the adhesive agent may be conductive adhesive agent, and the circuit boards are electrically connected to each other by the metal piece.

According to a third aspect of the present invention, there is provided an electronic circuit device including a plurality of circuit boards which have electronic parts mounted thereon and are three-dimensionally assembled, wherein the plural circuit boards are assembled in the thickness direction through spacers each of which comprises a metal piece, and both the ends of each metal piece are fixed to circuit boards at both the sides of the metal piece by solder. Here, both the ends of the metal piece may be soldered to the circuit boards at both the sides thereof by the solder materials which are different in melting point (temperature). Further, the electronic parts may be soldered to the circuit boards by solder material having the same melting point as the solder material having a higher melting point in the solder materials used to fix both the ends of the metal pieces to the circuit boards.

The connection structure of the circuit boards is preferably designed so that they are stacked through metal pieces serving as spacers so as to be electrically connected to one another through the metal pieces. Here, both the ends of each metal piece used for connecting the circuit boards may be connected to the circuit boards by different kinds of materials. Further, one end of the metal piece is connected to the corresponding one circuit board by solder while the other end of the metal piece is connected to the other circuit board by conductive adhesive agent. Alternatively, one end of the metal piece may be connected to the corresponding one circuit board by solder material having a high melting point while the other end of the metal piece is connected to the other circuit board by solder material having a low melting point.

According to the present invention, in the structure having a plurality of laminated circuit boards, the plural circuit boards can be easily separated (disassembled) without adversely effecting the parts mounted on the respective circuit boards. Further, the distance in the thickness direction between the circuit boards, that is, the gap between the circuit boards can be set to any value in accordance with the dimension of the metal pieces.

### BRIEF DESCRIPTION OF THE DRAWINGS

FIG. 1 is a longitudinal-sectional view showing the construction of an electronic circuit device;

FIG. 2 is an enlarged longitudinal-sectional view showing the main part of the electronic circuit device shown in FIG. 1;

FIG. 3 is another enlarged longitudinal-sectional view showing the main part of the electronic circuit device shown in FIG. 1;

FIGS. 4A to 4F are perspective views showing the outlooks of metal pieces;

FIGS. 5A to 5E are longitudinal-sectional views showing a method of manufacturing the electronic circuit device;

FIGS. 6A to 6D are longitudinal-sectional views showing another method of manufacturing the electronic circuit device;

FIGS. 7A and 7B are longitudinal-sectional views showing a repairing operation;

FIGS. 8A to 8D are longitudinal-sectional views showing another method of manufacturing the electronic device;

FIG. 9 is a longitudinal-sectional view showing a conventional electronic circuit device; and

FIG. 10 is a longitudinal-sectional view showing another conventional electronic circuit device.

### DETAILED DESCRIPTION OF THE PREFERRED EMBODIMENTS

Preferred embodiments according to the present invention will be described hereunder with reference to the accompanying drawings.

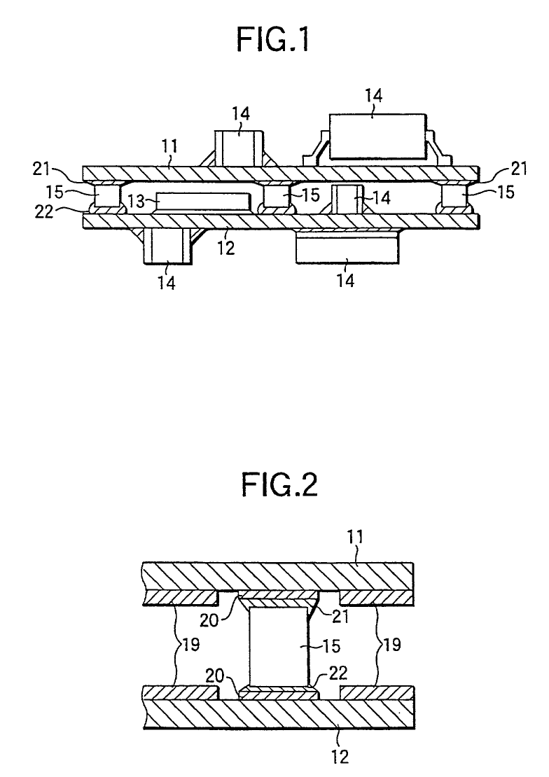

FIG. 1 shows the overall construction of an electronic circuit device according to a first embodiment of the present invention.

In this embodiment, upper and lower circuit boards 11, 12 are stacked so as to be spaced from each other at a predetermined interval. A semiconductor device 13 is mounted on the upper surface of the lower circuit board 12, and surface mounting parts 14 are arranged on the upper surface of the upper circuit board 11 and the upper and lower surfaces of the lower circuit board 12. Further, metal pieces 15 serving as spacers are arranged so as to keep the upper and the lower circuit boards 11, 12 at a distance from one another.

As described above, in this embodiment, the surface mounting parts 14 are mounted on the upper surface of the upper circuit board 11, and the surface mounting parts 14 are also mounted on the upper surface and the lower surface of the lower circuit board 12. The semiconductor device 13 is further mounted on the upper surface of the lower circuit board 12. In addition, the metal pieces 15 are arranged between the upper and lower circuit boards 11, 12 to connect the two circuit boards 11, 12.

The metal pieces 15 are formed of aluminum, copper, iron, steel, nickel or the like, and Ni-plating, Sn-plating, Au-plating or the like is conducted on the surface of each metal piece 15. The optimum surface treatment is selectively conducted on the surface of each metal piece 15 on the basis of the affinity between the metal pieces and upper and lower joint materials 21, 22 shown in FIG. 2.

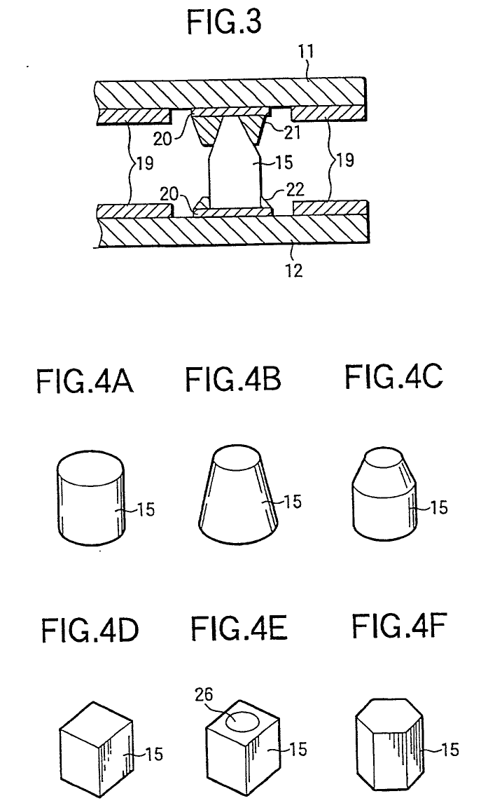

Each metal piece 15 may be designed not only to have a cylindrical shape as shown in FIG. 2, but also to have a tapered tip portion such as a conical shape as shown in FIG. 3 so as to keep the joint strength and make the distance between the metal piece and the neighboring part narrow. The dimension of the metal piece 15 in the thickness direction of the circuit boards 11, 12 may be set to any value in accordance with the height of the electronic parts 13, 14 mounted between a pair of circuit boards 11, 12.

FIGS. 4A to 4F show various shapes of the metal pieces 15 arranged between the pair of circuit boards 11, 12. Here, the metal piece 15 shown in FIG. 4E is designed to have a square pole shape and be equipped with a recess portion 26 on each of the upper and lower end faces thereof.

For the connection between each of the upper and lower circuit boards 11, 12 and each metal piece 15, solder is used for one of the connection portion between the upper circuit board 11 and each metal piece 15 and the connection portion between the lower circuit board 12 and each metal piece 15 while material different from the solder is used for the other connection portion. Here, conductive adhesive agent, for example, may be used as the material different from the solder.

As the conductive adhesive agent used in this embodiment is a material obtained by kneading conductive particles of Ag, Cu or the like into epoxy resin, polyester resin or the like serving as a binder for binding these conductive particles to one another. Further, the conductive adhesive agent is preferable a non-bridging type thermoplastic adhesive agent which has a softening point (for example, 120 to 150° C.) not more than the melting point of the solder (200 to 220° C.), has a remarkable difference between the adhesive strength under the normal temperature environment and that under the heated environment, and also can be solved with organic solvent to be removed as occasion demands.

Next, the method of manufacturing the electric circuit as shown in FIG. 1 will be described.

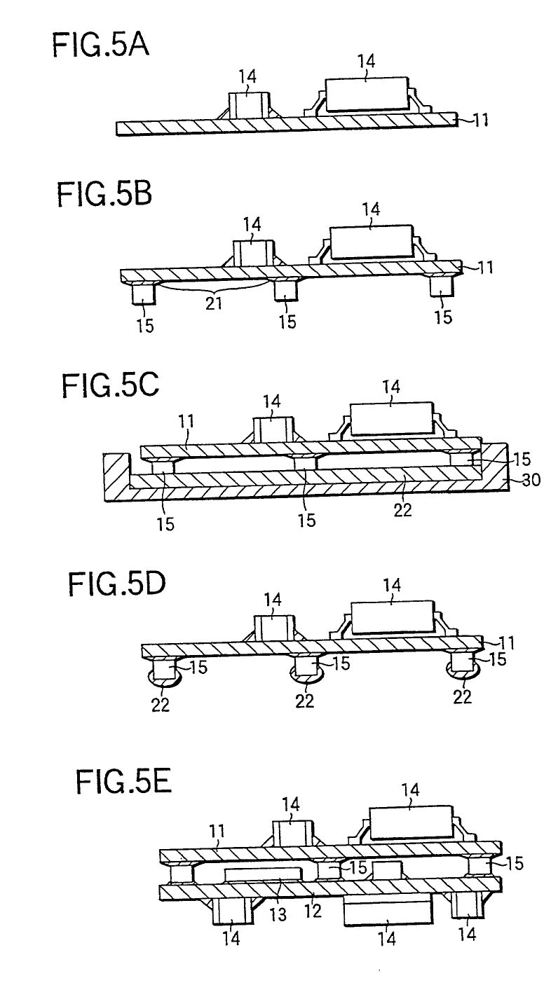

FIGS. 5A to 5E show an embodiment of the manufacturing method.

First, the surface mounting parts 14 are mounted on the upper surface of the upper circuit board 11 as shown in FIG. 5A. Subsequently, the metal pieces 15 are mounted through solder 21 on the lower surface of the upper circuit board 11 which is connected to the lower circuit board 12 (see FIG. 5B). The solder 21 used in this embodiment may be formed of the same material as the solder used to mount the surface mounting parts 14 on the upper surface of the circuit board 11.

Subsequently, in order to fix the lower circuit board 12 to the metal pieces 15 soldered to the upper circuit board 11, the conductive adhesive agent 22 serving as connecting material is supplied. The supply of the conductive adhesive agent 22 as described above is carried out as follows as shown in FIG. 5C. That is, the conductive adhesive agent 22 is supplied to a transfer plate 30 for which the flatness degree is known, and it is set to have a fixed thickness (for example, about 0.1 to 0.05 mm) by squeegee or the like. Under this state, the upper circuit board 11 is stationarily put on the transfer plate 30 to immerse the tip portions of the metal pieces 15 in the film of the conductive adhesive agent 22 for a fixed time. Thereafter, the metal pieces 15 are pulled up, whereby a desired amount of conductive adhesive agent 22 are fixedly transferred to the tip portions of the metal pieces 15 as shown in FIG. 5D.

Subsequently, as shown in FIG. 5E, the upper circuit board 11 having the metal pieces 15 to which the conductive adhesive agent 22 is attached is stationarily superposed on the lower circuit board 12 on which the surface mounting parts 14 and the semiconductor device 13 are mounted in advance. Under this state, the assembly of the upper and lower circuit boards 11, 12 is heated to harden the conductive adhesive agent 22. The electronic circuit device as shown in FIG. 1 is completed by the manufacturing process as described above.

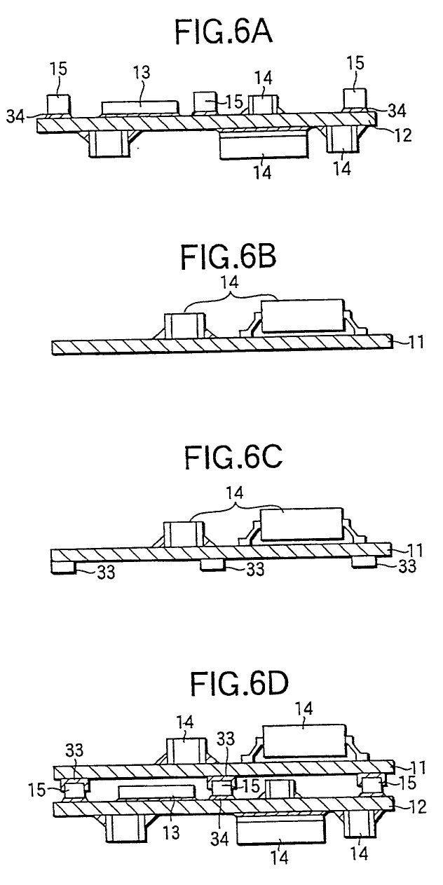

Next, another manufacturing method will be described with reference to FIGS. 6A to 6C.

In this embodiment, both the ends of each metal piece 15 constituting the spacer are joined to the circuit boards by using conductive adhesive agent 33 and solder 34, respectively. As shown in FIG. 6A, the surface mounting parts 14 are mounted on the upper and lower surfaces of the lower circuit board 12, and the semiconductor device 13 is mounted on the upper surface of the lower circuit board 12. Further, the surface mounting parts 14 are mounted on the surface of the upper circuit board 11 in advance as shown in FIG. 6B.

As shown in FIG. 6C, the conductive adhesive agent 33 is printed on the lower surface of the upper circuit board 11. This printing operation is carried out as follows. That is, a metal screen having openings which are formed at the positions corresponding to the connection portions of the metal pieces 15 to the lower circuit board 12 is superposed on the lower surface of the upper circuit board 11, and then the conductive adhesive agent 33 is coated on the lower surface of the upper circuit board 11 through the metal screen by a screen printing method. Thereafter, as shown in FIG. 6D, the upper circuit board 11 is superposed on the lower circuit board 12 on the upper surface of which the surface mounting parts 14, the semiconductor device 13 and the metal pieces 15 are mounted by the solder 34, and under this state the assembly of the upper and lower circuit boards 11, 12 is heated to harden the conductive adhesive agent 33, thereby achieving the electronic circuit device.

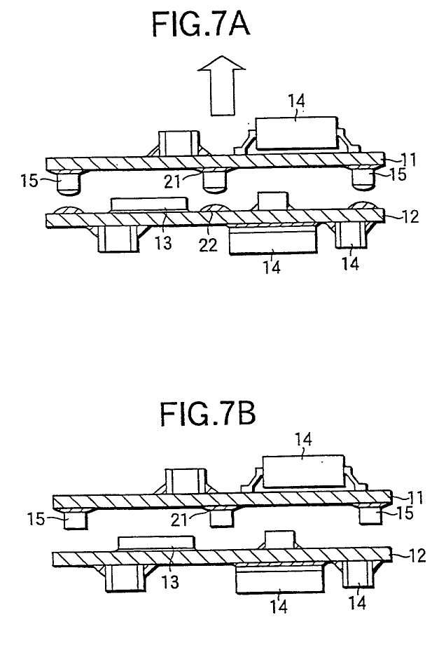

If any defective part or component is found in the semiconductor device 13 or the surface mounting parts 14 arranged between the circuit boards 11, 12 of the electronic circuit device manufactured by the manufacturing process as shown in FIGS. 5A to 5E or FIGS. 6A to 6D in an examination stage after the electronic circuit device having the structure as shown in FIG. 1 is completed, the connection portions of the conductive adhesive agent 22 are broken as shown in FIG. 7A by heating the electronic circuit device up to a temperature which is not more than the melting point of the solder 21 for connecting the electronic parts 13, 14 and the metal pieces 15 and also not more than the softening temperature of the conductive adhesive agent 22 for connecting one ends of the metal pieces 15 to the corresponding circuit board 12 and further applying slight force to the electronic circuit device. With this treatment, the upper and lower circuit boards 11, 12 are mutually separated from each other.

Accordingly, under this state, an exchange work or repair work of the parts 13, 14 between the circuit boards 11, 12 is carried out. Further, when these upper and lower circuits 11, 12 are attached to each other again, the metal pieces 15 and the conductive adhesive agent 22 remaining on the land of the upper surface of the circuit board 12 are wiped out with organic solvent such as acetone, xylene as shown in FIG. 7B, and then the same method as the processing shown in FIGS. 5C to 5E or FIGS. 6C to 6D is carried out again to join the upper and lower circuit boards 11, 12.

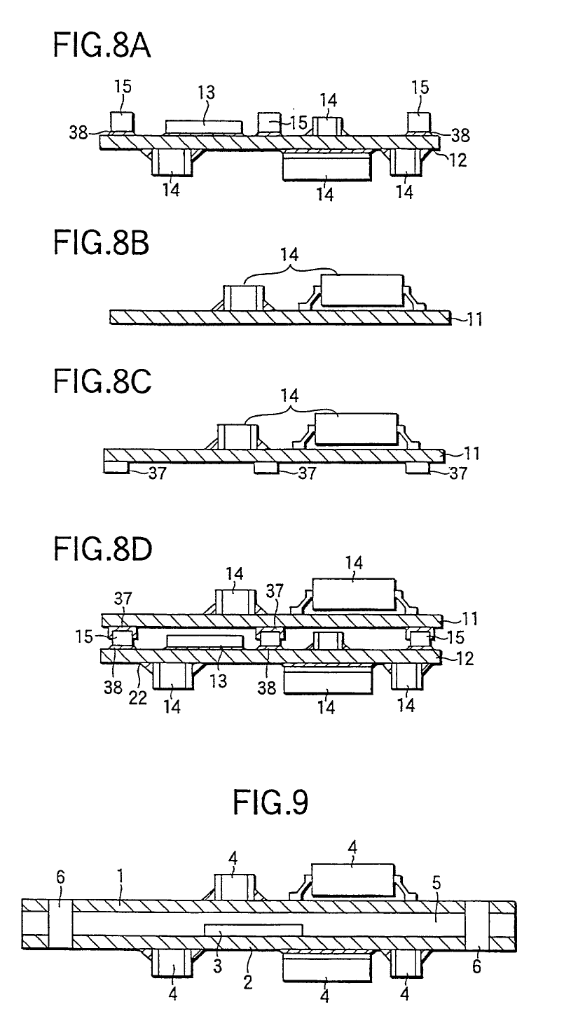

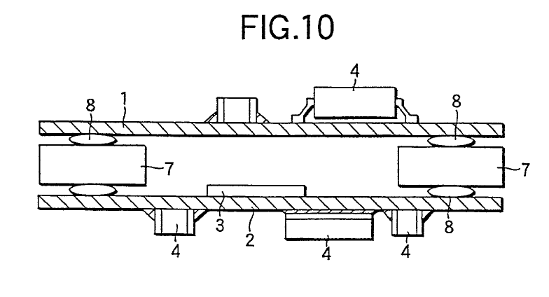

Next, another embodiment of the present invention will be described with reference to FIGS. 8A to 8D.

In this embodiment, the surface mounting parts 14 and the semiconductor device 13 are mounted on one circuit board 12 by solder having a high melting point, and at this time the metal pieces 15 are mounted by solder. Thereafter, the other ends of the metal pieces 15 and the other circuit board 11 are joined to each other by solder having a low melting point.

That is, as shown in FIG. 8A, the surface mounting parts 14 are mounted on the upper and lower surfaces of the lower circuit board 12, and the semiconductor device 13 is further mounted on the upper surface of the circuit board 12. Further, at the same time when the parts 13, 14 are mounted on the upper surface of the circuit board 12, the metal pieces 15 are mounted. The solder 38 used at this time has a normal melting point, that is, it is solder having a relatively high melting point.

Further, the surface mounting parts 14 are mounted on the upper surface of the upper circuit board 11 to be assembled with the circuit board 12 as shown in FIG. 8B. The surface mounting parts 14 and the semiconductor device 13 may be mounted on the lower surface of the circuit board 11 as occasion demands. In this case, solder having a normal melting point is used. The upper ends of the metal pieces 15 which are mounted on the lower circuit board 12 at one ends thereof by the solder 38 having the normal melting point are joined to the lower surface of the upper circuit board 11 by the solder 37 having the low melting point.

The same manufacturing process as the supply method of the conductive resin using the print method can be performed. The metal pieces 15 are mounted on the upper surface of the lower circuit board 12 by the solder having the normal melting point simultaneously with the surface mounting parts 14 (see FIG. 8A). Further, the surface mounting parts 14 are mounted on the upper surface of the upper circuit board 11 (see FIG. 8B). Thereafter, a metal screen having openings formed at the positions corresponding to the locations of the metal pieces 15 of the lower circuit board 12 is put on the lower surface of the circuit board 11, and then cream solder 37 having a low melting point is coated onto the lower surface of the circuit board 11 through the metal screen by the screen print method as shown in FIG. 8C. Subsequently, the upper circuit board 11 and the lower circuit board 12 are superposed on each other as shown in FIG. 8D and passed through a reflow furnace to melt the solder 37, thereby fixing the upper and lower circuit boards 11, 12 to each other.

The electronic circuit device having the above structure thus manufactured is heated up to a temperature at which the normal solder 38 is not melted, but the solder 37 having the low melting point is melted, thereby melting the solder 37 having the low melting point through which the upper ends of the metal pieces 15 and the upper circuit board 11 are joined to each other. Therefore, the upper and lower circuit boards are separated from each other and thus detached from each other. Accordingly, the parts 13, 14 between the circuit boards 11, 12 can be easily exchanged by new ones. When the parts 13, 14 are exchanged, the upper solder 37 coated on the lower surface of the upper circuit board 11 is removed, and the same process as described above is carried out to fabricate the electronic circuit device shown in FIG. 8D again.

Accordingly, according to this embodiment, in the structure of the plural laminated circuit boards 11, 12, the upper and lower circuit boards 11, 12 can be easily separated from each other to repair the electronic circuit device without adverse effecting the surface mounting parts 14 and the semiconductor device 13. Further, the distance between the upper and lower circuit boards 11, 12 can be set to any value by adjusting the dimension in the height direction of the metal pieces 15.

According to the present invention, in the electronic circuit device in which the plural circuit boards each having electronic parts mounted thereon are assembled three-dimensionally, the plural circuit boards are stacked in the thickness direction through the metal pieces having at least one ends fixed to the circuit boards.

Accordingly, according to the electronic circuit device, the plural circuit boards are electrically connected to one another through the metal pieces, and the plural circuit boards can be easily separated from one another by releasing the fixing between the metal pieces and one circuit board.

According to the present invention, in the electronic circuit device in which the plural circuit boards each having electronic parts mounted thereon are assembled three-dimensionally, the plural circuit boards are assembled in the thickness direction through the metal pieces serving as the spacers, and one ends of the metal pieces are soldered to one circuit board while the other ends of the metal pieces are fixed to the other circuit board by the adhesive agent having the melting point lower than that of the solder.

Accordingly, according to the electronic circuit device, the plural circuit boards are electrically connected to one another by the metal pieces, and by heating the electronic circuit device at a temperature at which the solder is not melted and the adhesive agent is softened, the fixing between the metal pieces and one circuit board can be released to repair the electronic circuit board or the like without melting the solder for fixing the electronic parts to the other circuit board.

According to the present invention, in the electronic circuit device in which the plural circuit boards each having electronic parts mounted thereon are assembled three-dimensionally, the plural circuit boards are assembled in the thickness direction through the metal pieces serving as the spacers, and both the ends of the metal pieces are joined to the circuit boards by the solder.

Accordingly, according to the electronic circuit device, the connection between the circuit boards at both the sides can be performed by the metal pieces, and also the circuit boards at both the sides can be mutually separated from each other by melting the solder at one ends of the metal pieces. Particularly, if the solder materials for soldering both the ends of the metal pieces to the circuit boards at both the sides respectively are made different in melting point and the electronic parts are soldered to the circuit boards by using the solder having the same melting point as the solder having a higher melting point in the solder materials, the metal pieces can be separated from the corresponding circuit board without melting the solder of the mounting parts by heating up to the temperature corresponding to the melting point of the solder having the low melting point.

What is claimed is:

1. An electronic circuit device including a plurality of circuit boards which have electronic parts mounted thereon and are three-dimensionally assembled, characterized in that said plural circuit boards are stacked in the thickness direction through metal pieces at least one ends of which are fixed to the circuit boards.

2. The electronic circuit device as claimed in claim 1, wherein both ends of each metal piece are fixed to said circuit boards at both the sides thereof by materials which are different in melting point.

3. An electronic circuit device including a plurality of circuit boards which have electronic parts mounted thereon and are three-dimensionally assembled, characterized in that said plural circuit boards are assembled in the thickness direction through spacers each of which comprises a metal piece, and one end of each metal piece is fixed to one circuit board by solder while the other end of said metal piece is fixed to another circuit board by adhesive agent having a melting point lower than the solder.

4. The electronic circuit device as claimed in claim 3, wherein said adhesive agent is conductive adhesive agent, and said circuit boards are electrically connected to each other by said metal pieces.

5. An electronic circuit device including a plurality of circuit boards which have electronic parts mounted thereon and are three-dimensionally assembled, characterized in that said plural circuit boards are assembled in the thickness direction through spacers each of which comprises a metal piece, and both the ends of each metal piece are fixed to said circuit boards at both the sides of the metal piece by solder.

6. The electronic circuit device as claimed in claim 5, wherein both the ends of each metal piece are soldered to said circuit boards at both the sides thereof by the solder materials which are different in melting point.

7. The electronic circuit device as claimed in claim 6, wherein said electronic parts are soldered to said circuit boards by solder material having the same melting point as the solder material having a higher melting point in said solder materials used to fix both the ends of said metal pieces to said circuit boards.
